(19) United States
(12) Patent Application Publication
(10) Pub. No.: US 2013/0105800 A1
(43) Pub. Date: May 2, 2013

(54) THIN FILM TRANSISTOR ARRAY SUBSTRATE AND MANUFACTURE METHOD THEREOF

(71) Applicant: Tsunglung Chang, Shenzhen (CN)

(72) Inventor: Tsunglung Chang, Shenzhen (CN)

(73) Assignee: SHENZHEN CHINA STAR OPTOELECTRONICS TECHNOLOGY CO.,LTD., Shenzhen (CN)

(21) Appl. No.: 13/379,835

(22) PCT Filed: Nov. 7, 2011
(86) PCT No.: PCT/CN2011/081879

§ 371 Date: Dec. 21, 2011

(30) Foreign Application Priority Data
Nov. 1, 2011 (CN) 201110339469.4

(51) Int. Cl. H01L 33/08

(52) U.S. Cl. 257/59; 257/72; 438/34; 257/E33.053

(57) ABSTRACT

Disclosed are a thin film transistor array substrate and a manufacture method thereof. The thin film transistor array substrate comprises scan lines parallel with each other, data lines intersect with the scan lines insulatively and orthogonally, a pixel unit defined by any two adjacent scan lines and any two adjacent data lines, and a capacitor line between any two adjacent scan lines, wherein an elongate hole is along the capacitor line on the capacitor line, and at a junction of the capacitor line and the data line, and comprises auxiliary capacitor lines symmetrically arranged along the data line and at two sides of the capacitor line corresponding to two hole walls of the elongate hole. By employing the present invention, it is easy to cut off the connection between the auxiliary capacitor line and the capacitor line under circumstance without increasing the manufacture difficulty of the auxiliary capacitor line.

### BACKGROUND OF THE INVENTION

1. Field of the Invention

The present invention generally relates to a liquid crystal display field, and more particularly to a thin film transistor array substrate and manufacture method thereof.

2. Description of Prior Art

In prior liquid crystal displays, and more particularly in the thin film transistor liquid crystal displays, the Indium Tin Oxides area is generally attended to be larger to increase the aperture ratio. However, the stray capacity effect may occur therefor. Namely, the stray capacitor exists between the pixels and the data lines may cause bad display of the liquid crystal panel.

For reducing the stray capacity effect, auxiliary capacitor lines are added into the thin film transistor array substrate in general. The auxiliary capacitor lines (or so called shield metal) are positioned close to the data lines. In the manufacture processes of the thin film transistor array substrate, lots of conducting particles are generated frequently. Some of these conducting particles are removed by a washer. Other some of these conducting particles remain on the thin film transistor array substrate. The remained conducting particles can cause defects, light spots, bright lines, dark lines, little light spots, little dark lines, little light spots and etc. when the liquid crystal display is lighted on. For eliminating the defects, repairs are required to the liquid crystal display panel for removing the conducting particles.

As shown in FIG. 1, which depicts a partial diagram of a thin film transistor array substrate according to prior art, a data line 3 and a scan line 1 in figure intersect insulatively and orthogonally. A thin film transistor 4 is positioned close to the intersection. The thin film transistor 4 comprises a source 4S, a gate 4G and a drain 4D. A pixel electrode 5 is positioned in the area surrounded by two adjacent scan lines 1 and two adjacent data lines 3. A capacitor line 2 is positioned between two adjacent scan lines 1. Auxiliary capacitor lines 6 are positioned near the data lines 3. The auxiliary capacitor line 6 comprises a cut out portion 6b and a main portion 6a. In case that some conducting particles remain between the auxiliary capacitor line 6 and the data line 3, the conducting particles may cause a short circuit between the auxiliary capacitor line 6 and the data line 3 and accordingly, a pixel light spot can appear. For eliminating the effect of these conducting particles to the liquid crystal display panel, the cut out portion 6b of the auxiliary capacitor line 6 can be cut off to separate the auxiliary capacitor line 6 and the capacitor line 2.

However, such design in the prior art complicates the manufacture process of the auxiliary capacitor lines.

### SUMMARY OF THE INVENTION

An objective of the present invention embodiments is to provide a thin film transistor array substrate and a manufacture method thereof for easily cutting off the connection between the auxiliary capacitor line and the capacitor line under circumstance without increasing the manufacture difficulty of the auxiliary capacitor line.

For solving the aforesaid technical problems, the present invention provides a thin film transistor array substrate, comprising a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines, wherein,

the thin film transistor array substrate comprises an elongate hole along an extension direction of the capacitor line on the capacitor line, and the elongate hole is at a junction of the capacitor line and the data line, and comprises auxiliary capacitor lines symmetrically arranged along an extension direction of the data line and at two sides of the capacitor line corresponding to two hole walls of the elongate hole.

The thin film transistor array substrate respectively comprises two auxiliary capacitor lines at two sides of the capacitor line corresponding to two hole walls of the elongate hole and the two auxiliary capacitor lines at the same side of the capacitor line are symmetrically arranged along an extension direction of the data line.

The elongate hole is symmetrical along the data line and a length of the elongate hole is larger than a distance between the two auxiliary capacitor lines at the same side which are symmetrically arranged along the data line.

The elongate hole can be a rectangle hole which a length direction follows an extension direction of the capacitor line.

The range of an area s of the elongate hole at one side of the data line is 1≦s≦16 and the unit is square microns.

The present invention embodiment also provides a thin film transistor array substrate, comprising a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines,

the thin film transistor array substrate comprises an elongate hole along an extension direction of the capacitor line on the capacitor line, and the elongate hole is at a junction of the capacitor line and the data line and is symmetrical along the data line;

the thin film transistor array substrate comprises two auxiliary capacitor lines at two sides of the capacitor line corresponding to two hole walls of the elongate hole and the two auxiliary capacitor lines at the same side of the capacitor line are symmetrically arranged along an extension direction of the data line.

The elongate hole is symmetrical along the data line and a length of the elongate hole is larger than a distance between the two auxiliary capacitor lines at the same side which are symmetrically arranged along the data line.

The elongate hole can be a rectangle hole which a length direction follows an extension direction of the capacitor line.

The range of an area s of the elongate hole at one side of the data line is 1≦s≦16 and the unit is square microns.

Correspondingly, the present invention embodiment also provides a manufacture method of a thin film transistor array substrate, comprising:

forming a thin film transistor array substrate, wherein the thin film transistor array substrate comprises a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines;

forming an elongate hole along an extension direction of the capacitor line on the capacitor line, wherein the elongate hole is at a junction of the capacitor line and the data line, and auxiliary capacitor lines symmetrically arranged along an extension direction of the data line and at two sides of the capacitor line corresponding to two hole walls of the elongate hole for forming cut out portions of connecting the capacitor line and the auxiliary capacitor line between two hole walls of the elongate hole and the two sides of the capacitor lines corresponding to the two hole walls;

detecting whether a short circuit occurs between the auxiliary capacitor line and the data line;

cutting off the cut out portions to disconnect the short circuit between the auxiliary capacitor line and the capacitor line when the short circuit is detected.

The thin film transistor array substrate respectively comprises two auxiliary capacitor lines at two sides of the capacitor line corresponding to two hole walls of the elongate hole and the two auxiliary capacitor lines at the same side of the capacitor line are symmetrically arranged along an extension direction of the data line.

The elongate hole is symmetrical along the data line and a length of the elongate hole is larger than a distance between the two auxiliary capacitor lines at the same side which are symmetrically arranged along the data line.

The elongate hole is a rectangle hole which a length direction follows an extension direction of the capacitor line.

The cut out portion is cut off by laser cutting.

In the embodiments of the present invention, some special design is not required for the auxiliary capacitor line but the elongate hole is added in the capacitor line connecting therewith to realize an easy cut off for the connection between the auxiliary capacitor lines at two sides of the capacitor line corresponding to two hole walls of the elongate hole without increasing the design complexity of the auxiliary capacitor line.

### BRIEF DESCRIPTION OF THE DRAWINGS

For a better understanding of the aforementioned content of the present invention, preferable embodiments are illustrated in accordance with the attached figures for further explanation. Obviously, the following figures are embodiments of the present invention. It is easy for a person skilled in the art to derive other embodiments from these figures.

FIG. 1 depicts a partial diagram of a thin film transistor array substrate according to prior art;

FIG. 2 depicts a partial plan of a thin film transistor array substrate according to a first preferable embodiment of the present invention;

FIG. 3 depicts a partial plan of a thin film transistor array substrate according to a second preferable embodiment of the present invention;

FIG. 4 depicts a mark diagram of an area of an elongate hole at one side of a data line shown in the first preferable embodiment of the present invention;

FIG. 5 depicts a flowchart of a manufacture method of a thin film transistor array substrate according to the preferable embodiments;

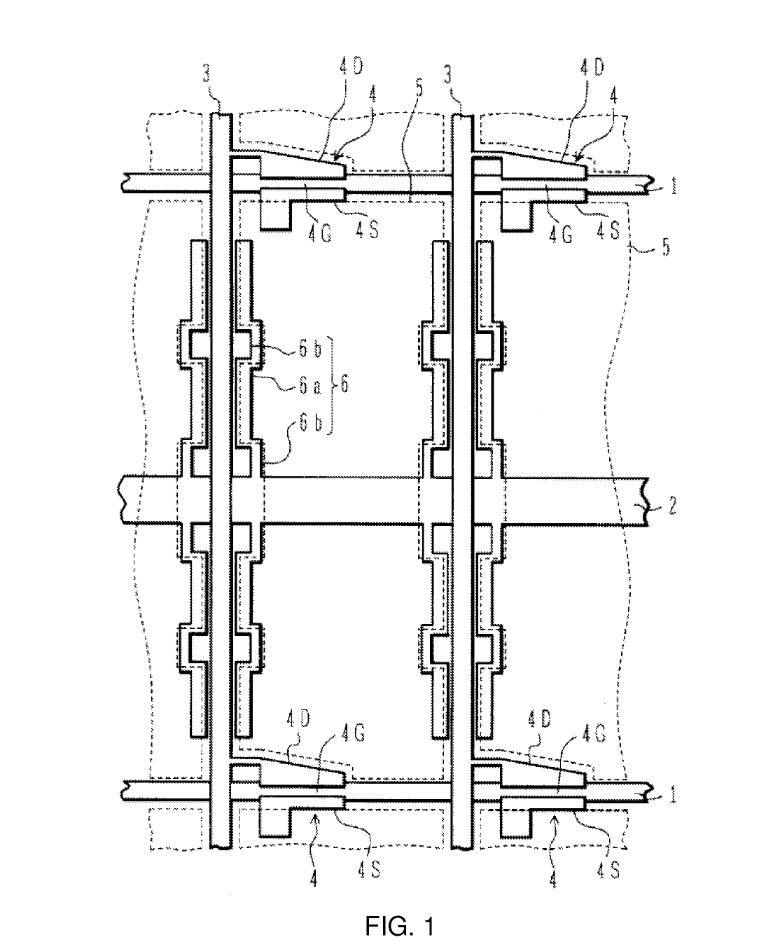

### DETAILED DESCRIPTION OF THE INVENTION

The following clear and full descriptions for the respective embodiments are specific embodiments capable of being implemented for illustrations of the present invention with referring to appended figures. Obviously, the described embodiments merely reveal the present invention partially rather than all of the embodiments. According to the illustrations, it is easy for a person skilled in the art to derive other embodiments from these figures and all belongs to the scope of the appended claims.

In the embodiments of the present invention, an elongate hole is positioned at a position corresponding to a capacitor line around a junction of a capacitor line and a data line. Therefore, an auxiliary capacitor line at the junction can be formed as a T structure or an inverted T structure. The auxiliary capacitor line can be cut off by cutting the junction position of the T structure.

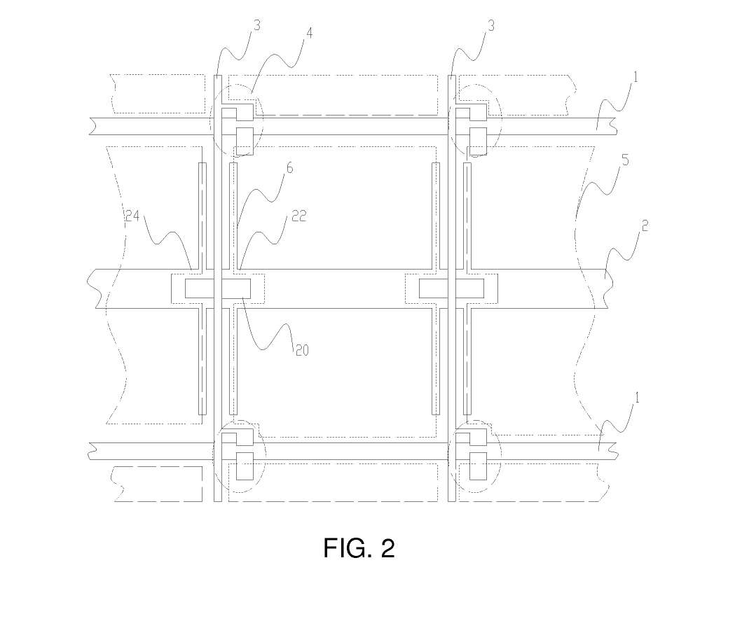

As shown in FIG. 2, which depicts a partial plan of a thin film transistor array substrate according to a first preferable embodiment of the present invention, the thin film transistor array substrate comprises a plurality of scan lines 1 parallel with each other, a plurality of data lines 3 intersect with the scan lines 1 insulatively and orthogonally, a pixel unit (not shown) defined by any two adjacent scan lines 1 and any two adjacent data lines 3. The pixel unit comprises a thin film transistor 4, pixel electrode 5 (the area surround by the dotted lines). Furthermore, the thin film transistor array substrate further comprises a capacitor line 2 between any two adjacent scan lines 1.

The thin film transistor array substrate comprises an elongate hole 20 along an extension direction of the capacitor line 2 on the capacitor line 2. The elongate hole 20 is at a junction of the capacitor line 2 and the data line 3. The thin film transistor array substrate comprises auxiliary capacitor lines 6 symmetrically arranged along an extension direction of the data line 3 and at two sides of the capacitor line 2 corresponding to two hole walls of the elongate hole 20 for forming cut out portions 22, 24 of connecting the capacitor line 2 and the auxiliary capacitor line 6 between two hole walls of the elongate hole 20 and the two sides of the capacitor lines 2 corresponding to the two hole walls. By cutting off the cut out portions 22, 24, the disconnection of the capacitor line 2 and the auxiliary capacitor line 6 can be realized.

In the embodiment as shown in FIG. 2, the thin film transistor array substrate respectively comprises two auxiliary capacitor lines 6 at two sides of the capacitor line 2 corresponding to two hole walls of the elongate hole 20. The two auxiliary capacitor lines 6 at the same side of the capacitor line 2 are symmetrically arranged along an extension direction of the data line 3. The elongate hole 20 is a rectangle hole which a length direction follows an extension direction of the capacitor line 2. Relevantly, the elongate hole 20 does not overlap with the pixel electrode 5.

Certainly, the elongate hole 20 also can be symmetrical along the data line 3. Meanwhile, the length of the elongate hole 20 is larger than a distance between the two auxiliary capacitor lines 6 at the same side which are symmetrically arranged along the data line 3.

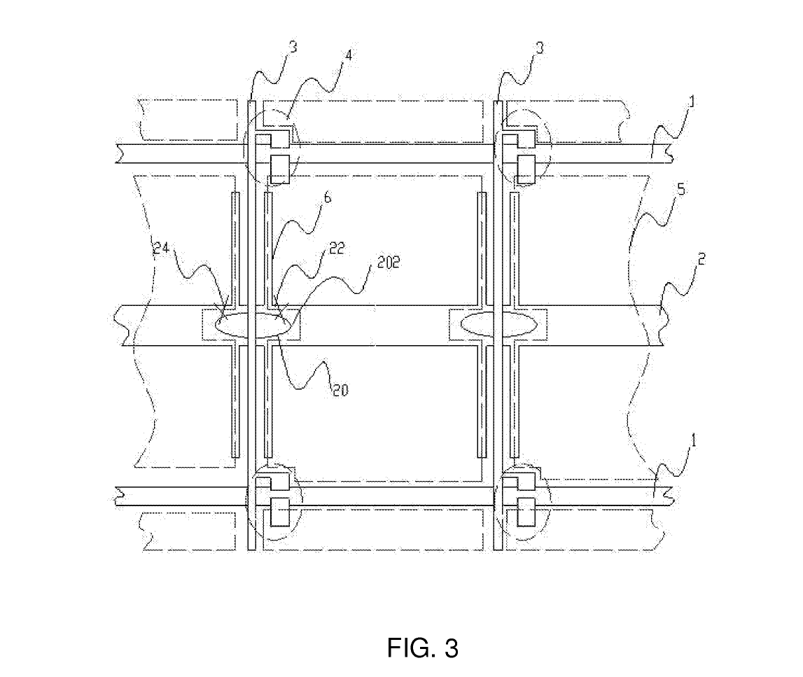

In other modified embodiments, the figure of the elongate hole 20 is not only limited to a rectangle but also other figures. As shown in FIG. 3, the figure of the elongate hole 20 can be an ellipse. The major axis direction of the ellipse can follow the extension direction of the capacitor line 2. The distance between the major axis end 202 of the ellipse and the data line 3 is larger than a distance between the auxiliary capacitor lines 6 at the same side and the data line 3. Alternatively, the figure of the elongate hole 20 can be a trapezoid or other polygons as long as the auxiliary capacitor lines 6 is positioned at the two sides of the capacitor line 2 corresponding to two hole walls of the elongate hole 20 and the aforesaid T structure or the aforesaid inverted T structure is formed. As shown in FIG. 3, the cut out portions 22, 24 marked by the cross ticks can be employed for cutting off the auxiliary capacitor lines 6 and the capacitor line 2.

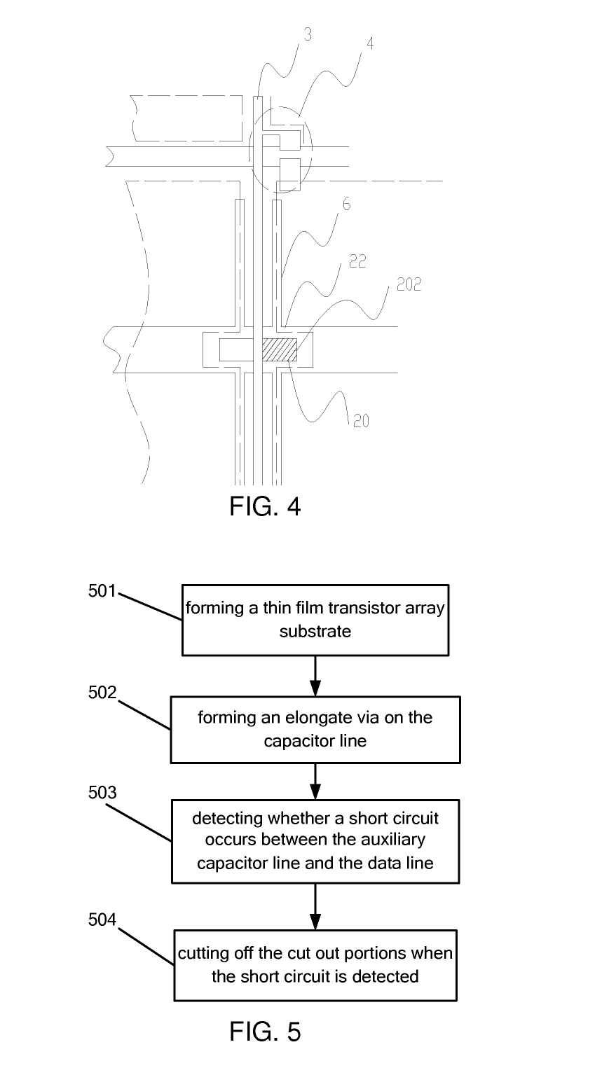

Meanwhile, a range of an area s of the elongate hole 20 at one side of the data line 3 can be 1≦s≦16 and the unit is square microns as indicated by the shadow area shown in FIG. 4.

Relevantly, FIG. 5 depicts a flowchart of a manufacture method of a thin film transistor array substrate according to the preferable embodiments. The manufacture method comprises steps of:

Step 501, forming a thin film transistor array substrate, wherein the thin film transistor array substrate comprises a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines.

Step 502, forming an elongate hole along an extension direction of the capacitor line on the capacitor line, wherein the elongate hole is at a junction of the capacitor line and the data line, and auxiliary capacitor lines symmetrically arranged along an extension direction of the data line and at two sides of the capacitor line corresponding to two hole walls of the elongate hole for forming cut out portions of connecting the capacitor line and the auxiliary capacitor line between two hole walls of the elongate hole and the two sides of the capacitor lines corresponding to the two hole walls.

As aforementioned in the embodiments, the elongate hole can have combinations of partial or all characteristics introduced hereafter: thin film transistor array substrate respectively comprises two auxiliary capacitor lines at two sides of the capacitor line corresponding to two hole walls of the elongate hole and the two auxiliary capacitor lines at the same side of the capacitor line are symmetrically arranged along an extension direction of the data line; the elongate hole is a rectangle hole which a length direction follows an extension direction of the capacitor line; the elongate hole is symmetrical along the data line and a length of the elongate hole is larger than a distance between the two auxiliary capacitor lines at the same side which are symmetrically arranged along the data line; a range of an area s of the elongate hole at one side of the data line is 1≦s≦16 and the unit is square microns.

Step 503, detecting whether a short circuit occurs between the auxiliary capacitor line and the data line

Step 504, cutting off the cut out portions to disconnect the short circuit between the auxiliary capacitor line and the capacitor line when the short circuit is detected. For example, a laser cutting can be employed for cutting off the cut out portion.

In the embodiments of the present invention, some special design is not required for the auxiliary capacitor line but the elongate hole is added in the capacitor line connecting therewith to realize an easy cut off for the connection between the auxiliary capacitor lines at two sides of the capacitor line corresponding to two hole walls of the elongate hole without increasing the design complexity of the auxiliary capacitor line.

As is understood by a person skilled in the art, the foregoing preferred embodiments of the present invention are illustrative rather than limiting of the present invention. It is intended that they cover various modifications and similar arrangements be included within the spirit and scope of the appended claims, the scope of which should be accorded the broadest interpretation so as to encompass all such modifications and similar structure.

What is claimed is:

1. A thin film transistor array substrate, comprising a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines, characterized in that,
the thin film transistor array substrate comprises an elongate hole along an extension direction of the capacitor line on the capacitor line, and the elongate hole is at a junction of the capacitor line and the data line, and comprises auxiliary capacitor lines symmetrically arranged along an extension direction of the data line and at two sides of the capacitor line corresponding to two hole walls of the elongate hole.

2. The thin film transistor array substrate according to claim 1, characterized in that the thin film transistor array substrate respectively comprises two auxiliary capacitor lines at two sides of the capacitor line corresponding to two hole walls of the elongate hole and the two auxiliary capacitor lines at the same side of the capacitor line are symmetrically arranged along an extension direction of the data line.

3. The thin film transistor array substrate according to claim 2, characterized in that the elongate hole is symmetrical along the data line and a length of the elongate hole is larger than a distance between the two auxiliary capacitor lines at the same side which are symmetrically arranged along the data line.

4. The thin film transistor array substrate according to one of claims 1 to 3, characterized in that the elongate hole is a rectangle hole which a length direction follows an extension direction of the capacitor line.

5. The thin film transistor array substrate according to claim 4, characterized in that a range of an area s of the elongate hole at one side of the data line is 1≦s≦16 and the unit is square microns.

6. A thin film transistor array substrate, comprising a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines, characterized in that,
the thin film transistor array substrate comprises an elongate hole along an extension direction of the capacitor line on the capacitor line, and the elongate hole is at a junction of the capacitor line and the data line and is symmetrical along the data line;
the thin film transistor array substrate comprises two auxiliary capacitor lines at two sides of the capacitor line corresponding to two hole walls of the elongate hole and the two auxiliary capacitor lines at the same side of the capacitor line are symmetrically arranged along an extension direction of the data line.

7. The thin film transistor array substrate according to claim 6, characterized in that the elongate hole is symmetrical along the data line and a length of the elongate hole is larger than a distance between the two auxiliary capacitor lines at the same side which are symmetrically arranged along the data line.

8. The thin film transistor array substrate according to claim 6, characterized in that the elongate hole is a rectangle hole which a length direction follows an extension direction of the capacitor line.

9. The thin film transistor array substrate according to claim 8, characterized in that a range of an area s of the elongate hole at one side of the data line is 1≦s≦16 and the unit is square microns.

10. A manufacture method of a thin film transistor array substrate, characterized in that the method comprises:
forming a thin film transistor array substrate, wherein the thin film transistor array substrate comprises a plurality of scan lines parallel with each other, a plurality of data lines intersect with the scan lines insulatively and orthogonally, a pixel unit defined by any two adjacent scan lines and any two adjacent data lines, and a capacitor line between any two adjacent scan lines;
characterized in that, the method further comprises:
forming an elongate hole along an extension direction of the capacitor line on the capacitor line, wherein the elongate hole is at a junction of the capacitor line and the data line, and auxiliary capacitor lines symmetrically arranged along an extension direction of the data line and at two sides of the capacitor line corresponding to two hole walls of the elongate hole for forming cut out portions of connecting the capacitor line and the auxiliary capacitor line between two hole walls of the elongate hole and the two sides of the capacitor lines corresponding to the two hole walls;
detecting whether a short circuit occurs between the auxiliary capacitor line and the data line;
cutting off the cut out portions to disconnect the short circuit between the auxiliary capacitor line and the capacitor line when the short circuit is detected.

11. The manufacture method according to 10, characterized in that the thin film transistor array substrate respectively comprises two auxiliary capacitor lines at two sides of the capacitor line corresponding to two hole walls of the elongate hole and the two auxiliary capacitor lines at the same side of the capacitor line are symmetrically arranged along an extension direction of the data line.

12. The manufacture method according to claim 11, characterized in that the elongate hole is symmetrical along the data line and a length of the elongate hole is larger than a distance between the two auxiliary capacitor lines at the same side which are symmetrically arranged along the data line.

13. The manufacture method according to one of claim 12, characterized in that the elongate hole is a rectangle hole which a length direction follows an extension direction of the capacitor line.

14. The manufacture method according to claim 10, characterized in that the cut out portion is cut off by laser cutting.
